(19) United States
(12) Patent Application Publication
(10) Pub. No.: US 2020/0140999 A1
(43) Pub. Date: May 7, 2020

(54) PROCESS CHAMBER COMPONENT CLEANING METHOD

(71) Applicant: Applied Materials, Inc., Santa Clara, CA (US)

(72) Inventors: Byung Seok KWON, San Jose, CA (US); Prashant Kumar KULSHRESHTHA, San Jose, CA (US); Kwangduk LEE, Redwood City, CA (US); Sarah Michelle BOBEK, Santa Clara, CA (US)

(21) Appl. No.: 16/182,407

(22) Filed: Nov. 6, 2018

(51) Int. Cl. C23C 16/44; B08B 7/00

(52) U.S. Cl. CPC C23C 16/4405; B08B 7/0035

(57) ABSTRACT

A method of cleaning a component of a semiconductor processing chamber is provided. The method includes exposing residue in a component to a process plasma containing a nitrogen-containing gas and an oxygen-containing gas. The residue in the component undergoes a chemical reaction, cleaning the component. The component is cleaned, restoring the component to the conditions before the process chemistry is run.

### BACKGROUND

### Field

Embodiments of the invention relate to a method, and more specifically, to a method of cleaning a component used in a processing chamber.

### Description of the Related Art

Cleaning processes are critical to film deposition in semiconductor manufacturing, as they affect the number of defects formed in the deposited film and on-wafer process stability. As semiconductor devices start to require higher memory densities, and therefore, thicker multi-stack structure (i.e. 3D VNAND, 3D ReRAM, DRAM), capability of completely cleaning the chamber within the shortest amount of time is critical to dramatically increase the wafer throughput. Within current cleaning processes, as film thickness is scaled to meet high aspect ratio (HAR) application requirements, the clean time will likewise need to be increased.

High temperature (>600° C.) carbon chemical vapor deposition (CVD) processes are one of the most prevalent techniques for creating hardmasks for semiconductor device fabrication, due to the high etch selectivity (>1.5×) of these films compared to traditional plasma enhanced CVD (PECVD) carbon process (˜480° C.), and its chemical simplicity for cleaning. In order to implement thicker hardmasks in production, high throughput is necessary. As the thickness of the hardmask is increased, both deposition time and the clean time must be increased as well, reducing the wafer throughput.

However, one drawback to current cleaning methods is they are not effective enough to clean process chamber components at the throughput required for modern semiconductor manufacturing. In addition, increasing the radio frequency (RF) power to create a stronger plasma during a cleaning process creates unwanted deposition of residue on the process chamber components. Also, a method of cleaning that does not require removal of the process chamber components from a process chamber increases the ease of cleaning, and reduces down-time and cost for the operator.

Therefore, there is a need for a more effective cleaning method for contaminated semiconductor chamber components.

### SUMMARY

In one embodiment, a method of removing a residue from a processing chamber component is provided, including forming a residue on a surface of the processing chamber component that is disposed in a processing region of a process chamber, exposing a residue formed on the surface of the processing chamber component to a first process plasma while the surface of the processing chamber component is disposed within the processing region and is heated to a first temperature. The first process plasma comprises a nitrogen-containing gas and an oxygen-containing gas. The first process plasma is formed by radio frequency (RF) biasing the process chamber component.

In another embodiment, a method of removing a residue from a processing chamber component is provided, including exposing a residue formed on a processing chamber component that is disposed in a processing region of a process chamber to a first process plasma, while the processing chamber component is heated to a first temperature, and exposing the residue to a second process plasma while the processing chamber component is disposed in the processing region, while the processing chamber component is heated to a second temperature. The first process plasma comprises a nitrogen-containing gas. The second process plasma comprises an oxygen-containing gas.

In some embodiments, the combination of nitrogen and oxygen containing plasmas provide a more thorough cleaning of the surface of a process chamber component in a semiconductor system. The more thorough cleaning allows for a faster clean, and requires less frequent cleaning than traditional chemistries.

### BRIEF DESCRIPTION OF THE DRAWINGS

So that the manner in which the above-recited features of the present disclosure can be understood in detail, a more particular description of the embodiments, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a deposition chamber configured to deposit materials on a substrate, according to one embodiment.

FIG. 2A schematically illustrates a portion of a showerhead that includes a residue formed on a surface of the showerhead, according to one embodiment.

FIG. 2B schematically illustrates the portion of the showerhead with a reacted residue disposed on the surface of the showerhead, according to one embodiment.

FIG. 2C schematically illustrates the portion of the showerhead after the cleaning is performed, according to one embodiment.

FIG. 3A is a process flow diagram illustrating steps for cleaning a component, according to one embodiment.

FIG. 3B is a process flow diagram illustrating steps for cleaning a component, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure provided herein include a process of cleaning one or more process chamber components that include a residue formed thereon, in order to ensure a stable processing environment and the proper functioning of the process chamber. In some embodiments, the cleaning process includes exposing a residue formed on a semiconductor component to a process plasma, which causes the residue to undergo a chemical reaction that alters a property of the deposited residue. In some embodiments, the residue further reacts with components disposed in a second process plasma, which removes the residue from the process chamber component. In some embodiments, the process chamber component is a showerhead, and the cleaning process gases are flowed through the apertures in the showerhead in the same manner that a deposition chemistry (e.g., deposition precursor) is flowed through the apertures in the showerhead. Embodiments of the disclosure provided herein may be especially useful for, but are not limited to, cleaning a component disposed within a processing region of a semiconductor process chamber.

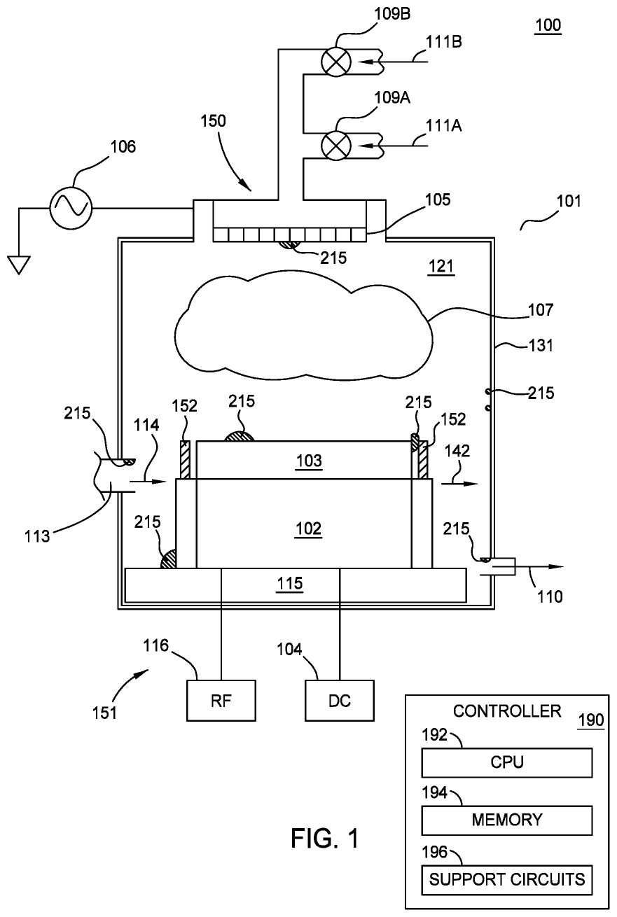

FIG. 1 illustrates a processing chamber assembly 100, according to one embodiment. As shown, the processing chamber assembly 100 includes processing chamber 101, injection system 150, and bias power system 151. The assembly 100 is any type of high performance semiconductor processing chamber known in the art, such as but not limited to an etcher, a cleaner, a furnace, or any other system to manufacture electronic devices. The processing chamber assembly 100 is one of the systems manufactured by Applied Materials, Inc. located in Santa Clara, Calif., according to one embodiment. The processing chamber 101 provides a chamber for growth of a layer, such as a hardmask layer on a substrate 103. The injection system 150 provides a process gas or process plasma to facilitate the growth of a material on the substrate 103 surface. The bias power system 151 provides a bias power to the substrate to facilitate the growth of a thin film or hardmask over a surface of the substrate 103, according to one embodiment. The components of the processing chamber assembly 100 work in concert to grow material on the provided substrate 103.

As shown, the processing chamber 101 includes a substrate 103, an electrostatic chuck (ESC) 102, a pedestal 115, an exhaust outlet 110, a retaining ring 152, and an opening 113. In some embodiments, the substrate 103 is a bare silicon or germanium wafer. In another embodiment, the substrate 103 further comprises a thin film. The substrate 103 can be a photomask, a semiconductor wafer, or other workpiece known to one of ordinary skill in the art of electronic device manufacturing. The substrate 103 comprises any material to make any of integrated circuits, passive (e.g., capacitors, inductors) and active (e.g., transistors, photo detectors, lasers, diodes) microelectronic devices, according to some embodiments. The substrate 103 comprises insulating (e.g., dielectric) materials that separate such active and passive microelectronic devices from a conducting layer or layers that are formed on top of them, according to one embodiment. In one embodiment, the substrate 103 is a semiconductor substrate that includes one or more dielectric layers e.g., silicon dioxide, silicon nitride, sapphire, and other dielectric materials. In one embodiment, the substrate 103 is a wafer stack including one or more layers. The one or more layers of the substrate 103 can include conducting, semiconducting, insulating, or any combination thereof layers. A hardmask layer is grown on the substrate 103, according to one embodiment. The hardmask layer includes a carbon (C) carbon containing material, according to one embodiment. In one example, the hardmask layer includes an amorphous carbon layer.

The substrate 103 is disposed on the electrostatic chuck 102, according to one embodiment. The substrate 103 is held in place on or aligned relative to the electrostatic chuck 102 by the retaining ring 152, according to one embodiment. In some embodiments, the temperature of the electrostatic chuck 102 can be controlled from a range from about 20° C. to about 650° C. by use of heating and cooling elements. In some embodiments, the substrate 103 is “chucked” to the substrate supporting surface of the electrostatic chuck 102 during processing to actively control the temperature of the substrate. The electrostatic chuck 102 is disposed over the pedestal 115, according to one embodiment. The pedestal 115 may be so heated by a heating element (not shown), such as a resistive heater embedded within pedestal, or a lamp (not shown) generally aimed at pedestal 115 or substrate 103 when thereon. Using such thermal control, substrate 103 may be maintained at a temperature between about 20° C. to about 650° C. In some embodiments, the retaining ring 152 and other similar positioned chamber components are formed from an aluminum (Al) containing material, a stainless steel alloy or a ceramic material, such as an aluminum alloy (e.g., 1000 series Al, 6000 series Al, 4000 series Al), an austenitic stainless steel (e.g., 304 SST, 316 SST), silicon material or alumina, quartz or aluminum nitride (AlN). In some alternate embodiments, the electrostatic chuck 102 is formed from a ceramic material, such as aluminum nitride (AlN), boron carbide (BC), or boron nitride (BN).

A substrate 103 is loaded through an opening 113 and placed on the electrostatic chuck 102. Processing chamber 101 is evacuated via the exhaust outlet 110. Exhaust outlet 110 is connected to a vacuum pump system (not shown) to evacuate volatile products produced during processing in the processing chamber 101, according to one embodiment. The components of the processing chamber 101 work in concert to provide a location for film growth on the provided substrate 103.

As shown, the bias power system 151 includes a direct current (DC) electrostatic chuck (ESC) power supply 104 and radio frequency (RF) source power 116. RF source power 116 is generally capable of producing an RF signal having a tunable frequency ranging from 2 to 160 MHz, with 13.56 or 2 MHz being a typical operating frequency, and power between about 1 kW and about 5 kW. In some embodiments, an electrode that is coupled to the RF source power 116 is disposed within the electrostatic chuck 102. The DC electrostatic chuck (ESC) power supply 104 is connected to a chucking electrode (not shown) disposed within the pedestal 115, according to one embodiment. The bias power system 151 provides a bias voltage across the substrate 103 to facilitate the treatment of the deposited film.

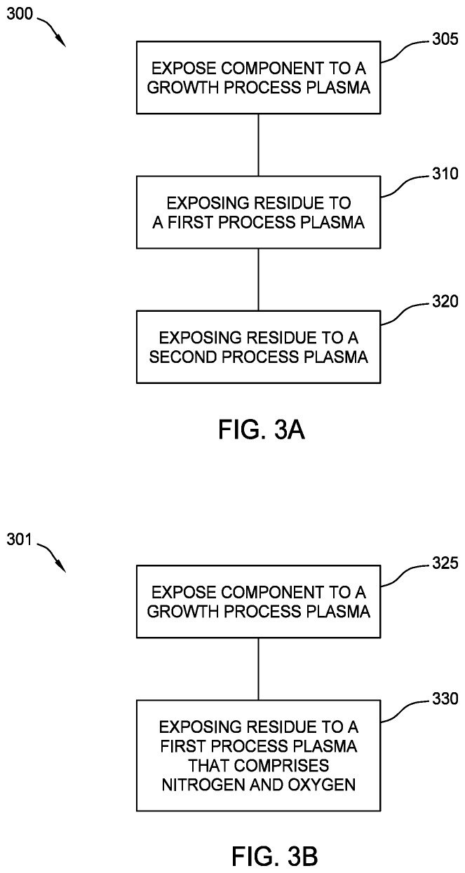

As shown, the injection system 150 includes showerhead 105, RF power source 106, and mass flow controller 109. One or more process gases 111, such as process gases 111A, 111B, are supplied through one or more mass flow controllers 109 (e.g., mass flow controllers 109A, 109B) to the chamber 101. A process gas 111 is a gas used for processing a thin film disposed within or formed within the processing region 121 of the processing chamber 101, according to one embodiment. In some embodiments, the thin film disposed within or formed within the processing region 121 of the processing chamber 101 is an amorphous carbon layer that is formed by use of a plasma enhanced CVD process. The one or more process gases 111A, 111B may include a first process gas and/or a second process gas, respectively, used to clean a component, as is described below (FIGS. 3A and 3B). A mass flow controller 109 controls the flow rate of a process gas 111 delivered to and through the showerhead 105, according to a specific recipe or application performed by a system. The RF power source 106 is generally capable of producing an RF signal having a tunable frequency ranging from 2 to 160 MHz, such as 13.56 MHz or 2 MHz being a typical operating frequency, and power between about 500 W and about 5 kW.

The specific recipe or application is controlled by means of a central controller 190, which gives specific temperature, timing, and process gas steps. The controller 190 can include a central processing unit (CPU) 192, a memory 194, and support circuits 196, e.g., input/output circuitry, power supplies, clock circuits, cache, and the like. The memory 194 is connected to the CPU 192. The memory is a non-transitory computable readable medium, and can be one or more readily available memory such as random access memory (RAM), read only memory (ROM), floppy disk, hard disk, or other form of digital storage. In addition, although illustrated as a single computer, the controller 190 could be a distributed system, e.g., including multiple independently operating processors and memories. This architecture is adaptable to various recipes based on programming of the controller 190 to control the order and of the flow of process gases. The computer-readable storage media will include non-volatile memory that contains computer readable instructions, such that when the computer readable instructions are executed by a processor (e.g., CPU 192), the processor will cause a computer implemented method to be performed, such as the implementation of one or more of the processing methods described herein.

When a plasma power applied from the RF power source 106 is applied to a portion of the chamber 101, a plasma 107 is formed in a processing region 121 over a surface of a substrate 103. In some embodiments, the RF power source 106 is coupled to the showerhead 105, which disperses the plasma to the substrate 103. The showerhead 105 includes an aluminum (Al) containing material, according to one embodiment. In one example, the showerhead includes an aluminum alloy, such as a 6061 alloy.

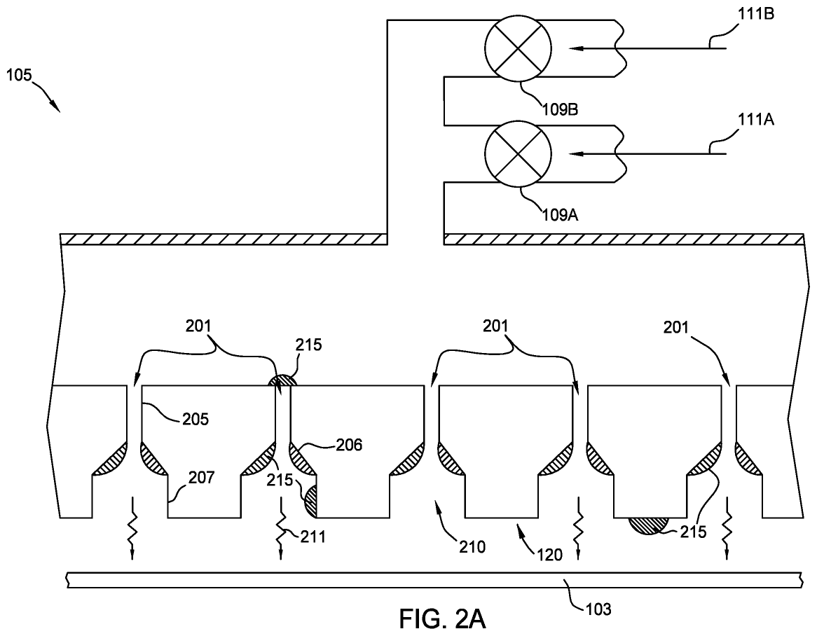

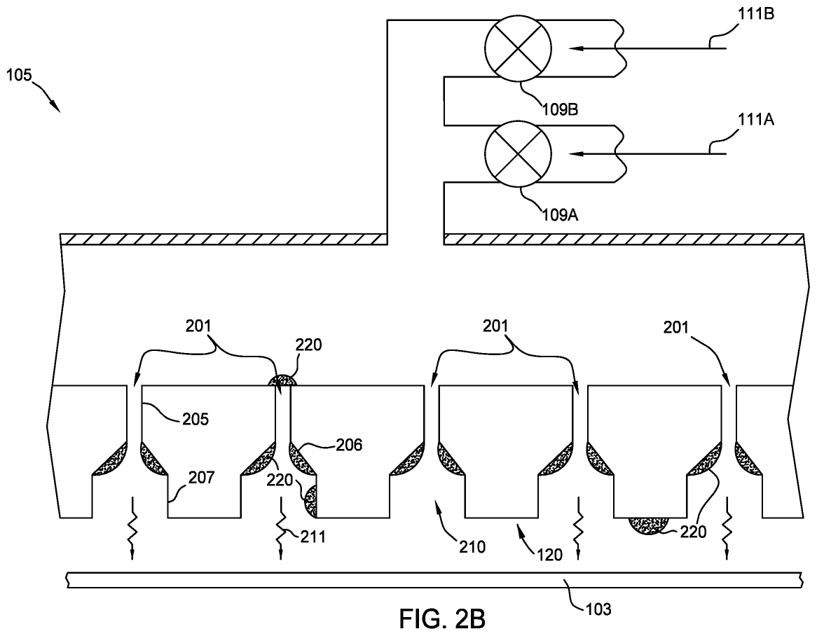

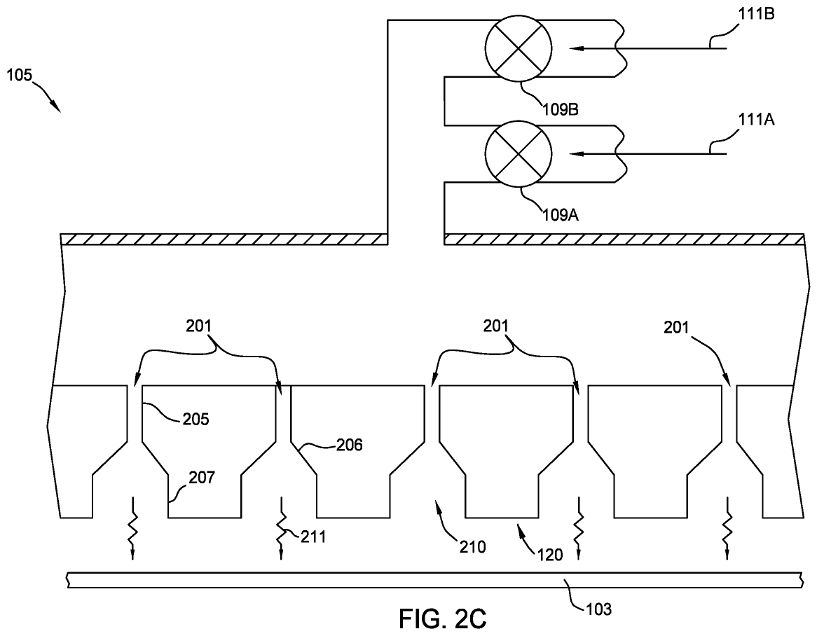

During normal use of the processing chamber 101, such as the deposition of a hardmask layer or other films on the substrate 103, unwanted residue 215 forms on various components of the processing chamber. The residue 215 may comprise at least carbon (C) and oxygen (O). The component on which the residue is formed can be a surface of the showerhead 105, the pedestal 115, the electrostatic chuck 102, the walls 131 of the processing chamber 101, and the like. In general, the residue 215 interferes with the proper functioning of the component. For example, residue 215 can flake off of components as particles, and fall on to the substrate 103, which prevents proper functioning of the resultant formed device. Residue 215 can also form in apertures 201 of the showerhead 105 (FIG. 2A), which reduces or plugs process gas flow. For example, if the component is a showerhead 105 (FIG. 2A), the residue 215 can impede the flow of the one or more process gases 111 into the processing region 121, slowing the rate of flow of the process gases 111 and increasing the time of deposition.

The residue 215 changes the average and local emissivity across the surface of the chamber component, which interferes with the average and local radiative heat transfer between components within the chamber 101, which cause thermal properties of the processing environment to drift over time, resulting in uneven process results from one processed substrate 103 to another processed substrate. The residue 215 can also be dislodged during operation and fall onto the substrate 103 below, causing imperfections in the layer that is being deposited on the substrate. In addition, the residue 215 can clog all or a portion of the apertures 201, severely reducing or completely blocking the flow of the process gases 111 through these apertures, which can cause deposition thickness nonuniformity on the surface of the substrate 103 during growth of the hardmask. If the residue 215 affected process chamber component is the pedestal 115, the residue 215 can cause a reduction of friction formed between a backside surface of the substrate and the surface of the pedestal, causing the substrate to slide during processing or during placement of the substrate on the electrostatic chuck 102. Substrate sliding leads to the substrate 103 to be incorrectly positioned on the surface of the electrostatic chuck 102 of the pedestal 115, leading to wafer chipping, deposition on unwanted portions of the electrostatic chuck 102 and other similar hardware damage. In addition, forming a residue 215 on the lifting components of the pedestal 115 causes the pedestal to be stuck in a certain position, interfering with proper deposition on the substrate 103 surface. If the residue 215 forms on the retaining ring 152, the residue can prevent the proper positioning of the substrate 103, which causes errors in deposition or patterning on the substrate. If the residue 215 forms in the opening 113, removal and insertion of the substrate 103 in the chamber 101 can be affected, preventing proper positioning of the substrate on the electrostatic chuck 102. If the residue 215 forms in the exhaust outlet 110, the residue 215 can cause the used processing gases to fail to exit the processing chamber 101, resulting in unwanted volatile species within the processing region 121 of the processing chamber 101.

FIG. 3A is a process flow diagram that includes a method 300 for cleaning a component, according to one embodiment. Although the method steps are described in conjunction with FIGS. 2A-C and 3A, persons skilled in the art will understand that any system configured to perform the processing steps, in any order, falls within the scope of the embodiments described herein. The method begins at step 305, where the component is exposed to a growth process plasma, such that a residue 215 is formed on the substrate 103 and various chamber components. For example, the residue 215 can form on the walls of the chamber 101, in the apertures 201 of the showerhead 105, on the faceplate 120 of the showerhead 105, or on the surface of the pedestal 115. In some embodiments, an amorphous carbon layer is formed on a substrate and residue 215 is formed on one or more of the chamber components by use of a plasma enhanced CVD process. The PECVD amorphous carbon layer formation process can include the use of a hydrocarbon precursor, such as a propene (C₃H₆), cyclobutane (C₄H₈), ethylene (C₂H₄), or similar precursor, and an inert gas, such as argon (Ar) or helium (He).

FIG. 2A illustrates a showerhead 105 after step 305 is performed. As shown, the showerhead 105 includes a plurality of apertures 201. An aperture 201 includes an inner channel 205, a sloped portion 206, an outer channel 207, and an outlet 210. The sloped portion 206 fluidly connects the inner channel 205 to the outer channel 207. The process gas 111 flows through the inner channel 205, through the sloped portion 206, and through the outer channel 207 into the process chamber 101. The width of the inner channel 205 is smaller than the width of the outer channel 207, according to one embodiment of the processing chamber 101. The width of the inner channel 205 is larger than the width of the outer channel 207, according to another embodiment of the processing chamber 101. The width of the inner channel 205 is the same as the width of the outer channel 207, and there is no sloped portion 206, according to another embodiment of the processing chamber 101. In one embodiment, the residue 215 is formed on the side of at least one of the apertures 201 by the process plasma 107. In one example, the residue 215 is formed on the sloped portion 206 of the aperture 201. The residue 215 can also be formed on the faceplate 120 of the showerhead 105, which changes the emissivity 211 emanating from the region of the faceplate on which the residue is positioned. The residue 215 can also be formed at the entrance of the inner channel 205, such that process gas flow is partially or completely blocked from flowing through the blocked inner channel. In some embodiments, the showerhead 105 is formed from an aluminum (Al) material, such as an aluminum alloy (e.g., 1000 series Al, 6000 series Al, 4000 series Al). In some alternate embodiments, the showerhead 105 is formed from a silicon material or a ceramic material, such as quartz, sapphire, alumina or boron nitride.

At step 310, the residue 215 is exposed to a first process plasma. The first process gas is flowed through the plurality of apertures 201 of the showerhead 105 while the showerhead 105 is in an operating position, and thus has not been removed from the processing chamber 101. The first process plasma contains a nitrogen-containing gas, according to one embodiment. The nitrogen-containing gas comprises nitrogen gas (N₂) or ammonia (NH₃), according to one embodiment. The nitrogen-containing gas may further comprise a neutral or carrier gas, such as helium (He) or argon (Ar), according to one embodiment. The carrier gas helps maintain the process environment at a desired pressure. The nitrogen-containing gas may be energized to a plasma by using the RF power source 106, which creates ions, such as N₂⁺, NH₂⁺, and NH⁺, or radicals, such as NH. The ions and radicals are reactive species, and cause and/or accelerate the residue 215 undergoing a chemical reaction with the reactive species. The RF power source 106 generates a bias that attracts ions formed in the plasma, thus pulling them towards the surface of showerhead 105 and helping them to penetrate the residue 215.

FIG. 2B illustrates a showerhead 105 after at least a portion of step 310 has been performed, according to one embodiment. After step 310 is performed, at least a portion of the residue 215 is changed into a modified residue 220. In one embodiment, the modified residue 220 comprises a higher percentage of nitrogen (N) than carbon (C) after the residue is exposed to the first process plasma. During processing, one or more portions of the process chamber 101 may be heated to a first temperature. In one example, a processing chamber component (e.g., showerhead 105) is heated to the first temperature. The first temperature can be varied from about 150° C. to about 650° C. The increased temperature increases the rate of the chemical reaction generated by the exposure of the residue 215 to the generated plasma. The pressure of the processing chamber 101 can be varied from about 1 Torr to about 20 Torr. The nitrogen-containing gas can be flowed at about 100 sccm to 15000 sccm. The nitrogen-containing gas can be flowed for about 1 second to about 20 minutes. The flow rate and flow time can be varied to optimize the time needed for cleaning the process chamber component, depending on the specific processing chamber component, chemical composition of the residue 215, and size of the processing chamber 101. In addition, the variation in flow time allows for deeper penetration of the residue 215 by radicals and ions, allowing the entire depth of the residue 215 to chemically react.

In some embodiments, the RF power source 106 is configured to apply an RF bias to one or more of the process chamber components (e.g., showerhead 105, retaining ring 152, etc.) so that ions generated in the plasma during step 310 are provided with enough energy (eV) to cause the plasma generated ions to interact directly with the material disposed at the surface of the chamber component. The RF power can vary from about 800 W to about 2500 W. The interaction of the reactive species with the material at the surface of the chamber component will cause a chemical reaction to occur, which will modify the chemical, optical and/or mechanical properties of the material at the surface of the chamber component. In one example, the RF power source 106 is configured to apply an RF bias to the showerhead 105 to cause nitrogen containing ions generated in the formed plasma to physically and/or chemically modify a carbon containing residue (e.g., amorphous carbon, polycrystalline carbon) formed on the exposed surfaces of the showerhead 105 and also physically and/or chemically modify the aluminum material disposed on the surface of the showerhead 105.

The modified surface of the process chamber component can help improve the process results for subsequent substrates that are processed in the processing chamber, by preventing the surface of the process chamber component from being attacked by subsequently provided reactive gases and stabilize the emissivity of the exposed surface of the process chamber component. In some embodiments, the process chamber component includes Al, an aluminum alloy or other similar material, and the cleaning step 310 results in a protective aluminum nitride (AlₓN_{y}) thin film formed on the surface of the component. The AlₓN_{y} thin film is more thermally stable than the residue 215 that includes the deposited film material, and compounds that will include Al, C, and O that form at the interface between the deposited residue 215 and the surface of the process chamber component, such as the surface of the showerhead 105. Thus, the AlₓN_{y} thin film prevents formation of the residue 215 during processing conditions.

In one example of step 310, the first temperature of one or more of the processing chamber components are maintained at about 150° C. to about 650° C., the pressure of the chamber is maintained at about 1 Torr to about 20 Torr, an RF power of about 800 W to about 5000 W is applied to the processing chamber component at an RF frequency, while process gases comprising nitrogen is provided for about 1 second to about 20 minutes. In one example, the process chamber component is an electrostatic chuck 102, a showerhead 105, an outlet 110, an opening 113, a pedestal 115, or a retaining ring 152. In one example, the process gas may include two gases that are provided at a flow rate of N₂ of about 100 sccm to about 15000 sccm, and the flow rate of Ar of about 100 sccm to about 15000 sccm.

In another example of step 310, the first temperature of the processing chamber component, such as the electrostatic chuck 102 or showerhead 105, is maintained at about 100° C. to about 650° C., the pressure of the chamber is maintained at about 4 Torr to about 20 Torr, and an RF power of about 800 W to about 5000 W is applied to the processing chamber component at an RF frequency of about 13.56 MHz while a nitrogen-containing gas comprising Ar and N₂ can be provided for about 10 seconds to about 600 seconds. In this example, a nitrogen-containing gas comprising Ar and N₂ can be provided at a flow rate of N₂ of about 800 sccm, and the flow rate of Ar of about 100 sccm. In some embodiments, the showerhead 105 is maintained at a temperature of about 100° C. to about 300° C., and/or the electrostatic chuck 102 is maintained at a temperature of about 400° C. to about 650° C.

In another example of step 310, the first temperature of the electrostatic chuck 102 is maintained at about 400° C. to about 650° C., the pressure of the chamber is maintained at about 4 Torr to about 6 Torr, an RF power of about 1000 W to about 2500 W is applied to the processing chamber component at an RF frequency of about 13.56 MHz, while a nitrogen-containing gas comprising N₂ is provided at a flow rate of N₂ of about 800 sccm, and a carrier gas, such as Ar is provided at a flow rate of about 100 sccm for about 10 to about 700 seconds.

In another example of step 310, the first temperature of the retaining ring 152 is maintained at about 600° C. to about 650° C., the pressure of the chamber is maintained at about 4 Torr, an RF power of about 1700 W is applied to the processing chamber component at an RF frequency of about 13.56 MHz, while a nitrogen-containing gas comprising N₂ is provided at a flow rate of N₂ of about 800 sccm, and a carrier gas, such as Ar is provided at a flow rate of about 100 sccm for about 90 seconds.

At step 320, the modified residue 220 is exposed to a second process plasma. At the start of step 320, a second process gas is flowed through the plurality of apertures 201 of the showerhead 105 while the process chamber component is positioned in its operating position, and thus has not been removed from the processing chamber 101, according to one embodiment. The second process plasma includes an oxygen-containing gas, according to one embodiment. The oxygen-containing gas may include oxygen gas (O₂) or water (H₂O), according to one embodiment. The oxygen-containing gas may further include a carrier gas, which may comprise helium (He) or argon (Ar). The carrier gas helps maintain the process environment at a desired pressure. The oxygen-containing gas may be energized into a plasma by using the RF power source 160, which creates ions, such as O⁺, O₂⁺, or OH⁻, or radicals, such as O or OH. The ions and radicals are reactive species, and cause the modified residue 220 to undergo a chemical reaction. FIG. 2C illustrates a showerhead 105 after step 330 occurs, according to one embodiment. The components in the second process plasma chemically react with the modified residue 220. The modified residue 220 is at least partially removed from the showerhead 105 by the exposure to the second process plasma, according to one embodiment. At least a portion of the modified residue 220 becomes volatile and is removed via the exhaust outlet 110 of the processing chamber 101, according to one embodiment. In one embodiment, the modified residue is an amorphous carbon containing residue, and thus the volatile species, for example, may include carbon monoxide (CO) and/or carbon dioxide (CO₂).

In some embodiments, the process chamber 101 is heated to a second temperature during step 320, and thus one or more of the processing chamber components are heated to a second temperature. The second temperature can be varied from about 150° C. to about 650° C. The increased temperature is used to increase the rate of the chemical reaction between the plasma generated species and the residue 215. In some embodiments, the second temperature can be different from the first temperature. The difference in the first and second temperatures can be useful in cases where the first process gas and the second process gas require different temperatures to provide an optimum rate of chemical reactions and desired chemical reaction products. The pressure of the processing chamber 101 can be maintained at a pressure from about 1 Torr to 20 Torr. The oxygen-containing gas can be flowed at about 100 sccm to about 15000 sccm. The oxygen-containing gas can be flowed for about 1 second to 20 minutes. The oxygen-containing gas can be flowed at a rate such that the ratio of the oxygen-containing gas to the nitrogen-containing gas flowed in step 320 is about 3-to-1 to about 50-to-1. The flow rate, flow time, and oxygen-containing gas to the nitrogen-containing gas ratio can be varied to optimize the time needed for cleaning the process chamber component, depending on the specific processing chamber component, chemical composition of the modified residue 220, and size of the processing chamber 101.

In one example of step 320, the second temperature of one or more of the processing chamber components are maintained at about 150° C. to about 650° C., the pressure of the chamber is maintained at about 1 Torr to about 10 Torr, an RF power of about 800 W to about 2500 W is applied to the processing chamber component at an RF frequency, while a process gas that includes oxygen is provided for about 10 seconds to about 20 minutes. In one example, the process chamber component is an electrostatic chuck 102, a showerhead 105, an outlet 110, an opening 113, a pedestal 115, or a retaining ring 152. In one example, the process gas may include an oxygen-containing gas that includes O₂ which can be provided at a flow rate of O₂ of about 100 sccm to about 15000 sccm, and a carrier gas, such as Ar at a flow rate of about 100 sccm to about 15000 sccm.

In one example of step 320, the second temperature of the processing chamber component, such as the electrostatic chuck 102 or the showerhead 105, is maintained at about 400° C. to about 650° C., the pressure of the chamber is maintained at about 4 Torr to about 10 Torr, an RF power of about 1500 W to about 2300 W is applied to the processing chamber component at an RF frequency of about 13.56 MHz while an oyxgen-containing gas is provided for about 10 seconds to about 80 seconds. In one example, the oyxgen-containing gas is provided by supplying a flow rate of O₂ of about 14000 sccm and a carrier gas, such as Ar is provided at a flow rate of about 100 sccm.

In one example of step 320, the second temperature of the electrostatic chuck 102 is maintained at about 600° C. to about 650° C., the pressure of the chamber is maintained at about 4 Torr to about 6 Torr, an RF power of about 1500 W to about 2300 W is applied to the processing chamber component at an RF frequency of about 13.56 MHz, while an oxygen-containing gas comprising O₂ is provided at a flow rate of O₂ of about 14000 sccm, and a carrier gas, such as Ar is provided at a flow rate of about 100 sccm for about 60 seconds.

The first treatment step 310 and second treatment step 320 can be sequentially repeated multiple times, in order to continue the cleaning of the component. It is believed that repeating the process steps can increase the cleaning of the process chamber component with each pass. The first and second treatment steps can be performed in any order or simultaneously. For example, the second treatment step 320 could be performed before the first treatment step 310 is performed. The overall process of cleaning the component will result in a better functioning of the component compared to the original component that was contaminated with residue. The process gas is chosen such that the method 300 will not result in unwanted etching of the processing chamber component itself.

In some embodiments of method 300, at least a portion of the first treatment step 310 and second treatment step 320 overlap and thus are performed simultaneously. In the overlapping portion of the method 300, the residue 215 found in the processing region of the process chamber is exposed to a plasma that contains both an oxygen-containing gas and a nitrogen-containing gas. In some embodiments of method 300, it may be desirable to first expose the residue 215 to a first process plasma formed using the process parameters found in the first treatment step 310 and then form a second plasma that includes a combination of process gases provided in the first treatment step 310 and second treatment step 320 (e.g., nitrogen containing gas and oxygen containing gas mixture). Alternately, in some embodiments of method 300, it may be desirable to first expose the residue 215 to a first process plasma formed using the process parameters found in the second treatment step 320 and then form a second plasma that includes a combination of process gases provided in the first treatment step 310 and second treatment step 320 (e.g., nitrogen containing gas and oxygen containing gas mixture). Examples, of process parameters that may be used at times when the first treatment step 310 and second treatment step 320 are performed simultaneously are described further below, such as the discussion in found in relation to method 301.

In some embodiments of method 300, it is desirable to include a process step that includes a combination of simultaneously performing the first treatment step 310 and second treatment step 320, and then ending the method 300 by performing at least a portion of either the first treatment step 310 or second treatment step 320. In some embodiments of method 300, at least a portion of either the first treatment step 310 or second treatment step 320 is performed, a combination of the first treatment step 310 and second treatment step 320 are simultaneously performed, and then at least a portion of either the first treatment step 310 or second treatment step 320 is performed on the residue 215 in the process chamber. In one example, the residue 215 is first exposed to a first process plasma formed using the process parameters (e.g., gas composition, process pressure, RF power, temperature, etc.) found in the first treatment step 310, then a second plasma is formed having a second set of process parameters (e.g., gas composition, process pressure, RF power, temperature, etc.), wherein the second plasma includes a combination of process gases provided in the first treatment step 310 and second treatment step 320, and then a third plasma is formed using the process parameters (e.g., gas composition, process pressure, RF power, temperature, etc.) found in the first treatment step 310.

### Alternate Process Example

FIG. 3B is a flow diagram of a method 301 for cleaning a component, according to another embodiment. Although the method 301 are described in conjunction with FIGS. 2A-C and 3B, persons skilled in the art will understand that any system configured to perform the method steps, in any order, falls within the scope of the embodiments described herein. The method begins at step 325, where the component is exposed to a growth process plasma, such that a residue 215 is formed on a surface of a process chamber component. FIG. 2A illustrates, for example, a showerhead 105 after step 325 occurs.

At step 330, the residue 215 is exposed to a first process plasma. At the start of step 330, a first process gas is flowed through the plurality of apertures 201 of the showerhead 105 while the process chamber component is positioned in its operating position, and thus has not been removed from the processing chamber 101, according to one embodiment. The first process plasma includes a nitrogen-containing gas and an oxygen-containing gas, according to one embodiment. The nitrogen-containing gas may include nitrogen gas (N₂) or ammonia (NH₃) and the oxygen-containing gas may include oxygen gas (O₂) or water (H₂O), according to one embodiment. The nitrogen-containing gas and the oxygen-containing gas may further include a carrier gas, which may comprise helium (He) or argon (Ar), according to one embodiment. The carrier gas helps maintain the process environment at a desired pressure. The nitrogen-containing gas and oxygen-containing gas may be energized into a plasma by using the RF power source 160, which creates ions, such as N₂⁺, NH₂⁺, NH⁺, O⁺, O₂⁺, or OH⁻, or radicals, such as NH, O, or OH. The ions and radicals are reactive species, and cause the residue 215 to undergo a chemical reaction. The RF power source 106 attracts ions through an electromagnetic reaction, pulling them toward the showerhead 105 and helping to penetrate the residue 215, chemically reacting with the entire volume of the residue.

FIG. 2C illustrates a showerhead 105 after step 330 occurs, according to one embodiment. The first process plasma chemically reacts with the residue 215, creating volatile species that exit the showerhead 105. The process chamber 101 is heated to a first temperature, and thus the processing chamber component is heated to a first temperature, according to one embodiment. The first temperature can be varied from about 150° C. to about 650° C. The increased temperature increases the rate of the chemical reaction. The pressure of the processing chamber 101 can be varied from about 1 to about 20 Torr. The ratio of flow rate between the oxygen-containing gas and the nitrogen-containing gas can be between about 3 to about 50. The flow rate, flow time, and oxygen-containing gas to the nitrogen-containing gas ratio can be varied to optimize the time needed for cleaning the process chamber component, depending on the specific processing chamber component, chemical composition of the residue 215, and size of the processing chamber 101. The step 330 is more efficient than the separate steps 310, 320, as it is performed simultaneously, and thus the residue 215 is removed in a single step, increasing throughput.

In one example of step 330, the first temperature of one or more of the processing chamber components are maintained at about 20° C. to about 650° C., the pressure of the chamber is maintained at about 1 Torr to about 10 Torr, an RF power of about 800 W to about 5000 W is applied to the processing chamber component at an RF frequency, a nitrogen-containing gas and a an oxygen-containing gas are provided for about 1 second to about 20 minutes. In one example, the process chamber component is an electrostatic chuck 102, a showerhead 105, an outlet 110, an opening 113, a pedestal 115, or a retaining ring 152. In one example, the nitrogen-containing gas includes N₂ that is provided at a flow rate of about 100 sccm to about 15000 sccm. In some configurations, a carrier gas, such as Ar is simultaneously provided at a flow rate of about 100 sccm to about 15000 sccm. In this example, the oxygen-containing gas includes O₂ which is provided at a flow rate of O₂ of about 100 sccm to about 15000 sccm.

In another example of step 330, the first temperature of a processing chamber component, such as the electrostatic chuck 102 or the showerhead 105, is maintained at is maintained at about 100° C. to about 650° C., the pressure of the chamber is maintained at about 4 Torr to about 10 Torr, an RF power of about 800 W to about 2500 W is applied to the processing chamber component at an RF frequency of about 13.56 MHz while a process gas is provided for between about 50 and about 60 seconds. In one example, the process gas includes N₂, and O₂ that is provided at a flow rate of about 800 sccm, and about 14000 sccm, respectively. In some embodiments, the showerhead 105 is maintained at a temperature of about 100° C. to about 300° C., and the electrostatic chuck 102 is maintained at a temperature of about 400° C. to about 650° C.

In another example of step 330, the first temperature of the electrostatic chuck 102 is maintained at about 400° C. to about 650° C., the pressure of the chamber is maintained at about 4 Torr to about 6 Torr, an RF power of about 1500 W to about 2000 W is applied to the processing chamber component at an RF frequency of about 13.56 MHz, a nitrogen-containing gas comprising Ar and N₂ is provided at a flow rate of N₂ of about 800 sccm, the flow rate of Ar of about 100 sccm, an oxygen-containing gas comprising O₂ is provided at a flow rate of O₂ of about 14000 sccm for about 50 s.

In another example of step 330, the first temperature of the showerhead 105 is maintained at about 100° C. to about 300° C., the pressure of the chamber is maintained at about 4 Torr to about 6 Torr, an RF power of about 1500 W to about 2000 W is applied to the processing chamber component at an RF frequency of about 13.56 MHz, while a process gas including Ar, O₂, and N₂ is provided for about 50 to about 90 seconds. In one example, the flow rate of N₂ is provided at about 800 sccm, the flow rate of Ar is provided at about 100 sccm, an oxygen-containing gas comprising O₂ is provided at a flow rate of O₂ of about 14000 sccm.

In some embodiments, the process chamber component comprises Al, and the cleaning method 300 results in a protective AlₓN_{y} thin film formed on the surface of the component. The AlₓN_{y} thin film is more thermally stable than the residue 215 comprising Al, C, and O. Thus, the AlₓN_{y} thin film prevents formation of the residue 215 during processing conditions.

Residue 215 in a component is exposed to a first process plasma 107 that includes a nitrogen-containing gas, which chemically reacts with the surface of the process chamber component and the residue to create a modified residue 220 and surface of the process chamber component. The modified residue 220 is exposed to a second process plasma 107 containing an oxygen-containing gas, which chemically reacts with the modified residue. The combination of the first and second process plasma removes the modified residue 220 from the component. The process is especially effective for, but not limited to, creating volatile species comprising Al, N, and O.

The combination of the nitrogen-containing gas and oxygen-containing gas provides a faster and more thorough cleaning than methods in the art, increasing throughput. In addition, the method works without removing the component from the operating position in the chamber 101, lowering the cost and time of disassembling the chamber. Also, formation of an AlₓN_{y} thin film prevents formation of the residue 215 during normal processing conditions.

While the foregoing is directed to implementations of the present invention, other and further implementations of the invention may be devised without departing from the basic scope thereof, and the scope thereof is determined by the claims that follow.

1. A method of removing a residue from a processing chamber component, comprising:
exposing the residue formed on a surface of the processing chamber component to a process plasma while the surface of the processing chamber component is disposed within a processing region of a processing chamber wherein:
the process plasma comprises a nitrogen-containing gas and an oxygen-containing gas,
the ratio of a flow rate between the oxygen-containing gas and the nitrogen-containing gas is between about 3 and about 50, and
the process plasma is formed by radio frequency (RF) biasing the processing chamber component.

2. The method of claim 1, wherein the processing chamber component comprises a showerhead comprising a plurality of apertures, wherein the showerhead comprises aluminum, and after exposing the showerhead to the process plasma the surface of the apertures comprises a thin film that comprises aluminum (Al) and nitrogen (N).

3. The method of claim 2, wherein the plurality of apertures comprise an inner channel, a sloped portion, and an outer channel, wherein the sloped portion fluidly connects the inner channel and the outer channel, and the residue is disposed on the sloped portion of at least one of the plurality of apertures.

4. The method of claim 2, wherein the RF bias applied to the showerhead includes applying between about 800 W and about 2500 W of RF power.

5. The method of claim 2, wherein the residue comprises carbon (C) and oxygen (O).

6. The method of claim 5, wherein the exposing the residue to the first process plasma causes the residue to undergo a chemical reaction, such that the residue comprises a higher percentage of nitrogen (N) than carbon (C) after the exposing the residue to the process plasma.

7. The method of claim 1, wherein the exposing the residue comprises:
exposing the residue to a first process plasma, wherein the first process plasma comprises the nitrogen-containing gas, while the processing chamber component is heated to a first temperature; and
exposing the residue to a second process plasma, wherein the second process plasma comprises the oxygen-containing gas, while the processing chamber component is heated to a second temperature.

8. The method of claim 7, wherein the processing chamber component comprises a showerhead having a plurality of apertures, the showerhead comprising aluminum (Al), and after exposing the showerhead to the first process plasma and the second process plasma the surface of the apertures comprises a thin film that comprises aluminum (Al) and nitrogen (N).

9. The method of claim 8, wherein the plurality of apertures have a sloped portion.

10. The method of claim 9, wherein the plurality of apertures comprise an inner channel- and an outer channel, wherein the sloped portion fluidly connects the inner channel and the outer channel, and the residue is disposed on the sloped portion of at least one of the plurality of apertures.

11. The method of claim 8, wherein a radio frequency (RF) bias is applied to the process chamber component during the exposing the residue.

12. The method of claim 8, wherein the residue comprises carbon (C) and oxygen (O).

13. The method of claim 12, wherein the exposing the residue to the first process plasma causes the residue to undergo a chemical reaction, such that the residue comprises a higher percentage of nitrogen (N) than carbon (C) than after the exposing the residue to the first process plasma.

14. The method of claim 7, wherein the first temperature and the second temperature are substantially equal.

15. A method of removing a residue from a processing chamber component, comprising:
exposing the residue formed on a surface of the processing chamber component to a process plasma while the surface of the processing chamber component is disposed within a processing region of a processing chamber wherein:
the process plasma comprises a nitrogen-containing gas and an oxygen-containing gas,
the ratio of a flow rate between the oxygen-containing gas and the nitrogen-containing gas is between about 3 and about 50,
the process plasma is formed by radio frequency (RF) biasing the processing chamber component, and
the residue comprises carbon (C) and oxygen (O).

16. The method of claim 15, wherein the processing chamber component comprises a showerhead comprising a plurality of apertures, wherein the showerhead comprises aluminum, and after exposing the showerhead to the process plasma the surface of the apertures comprises a thin film that comprises aluminum (Al) and nitrogen (N).

17. The method of claim 16, wherein the plurality of apertures comprise an inner channel, a sloped portion, and an outer channel, wherein the sloped portion fluidly connects the inner channel and the outer channel, and the residue is disposed on the sloped portion of at least one of the plurality of apertures.

18. A method of removing a residue from a processing chamber component, comprising:
exposing the residue formed on a surface of the processing chamber component to a process plasma while the surface of the processing chamber component is disposed within a processing region of a processing chamber wherein:
the process plasma comprises a nitrogen-containing gas and an oxygen-containing gas,
the ratio of a flow rate between the oxygen-containing gas and the nitrogen-containing gas is between about 3 and about 50,
the process plasma is formed by radio frequency (RF) biasing the processing chamber component,
the residue comprises carbon (C) and oxygen (O), and
the exposing the residue to the process plasma causes the residue to undergo a chemical reaction, such that the residue comprises a higher percentage of nitrogen (N) than carbon (C) than after the exposing the residue to the process plasma.

19. The method of claim 18, wherein the processing chamber component comprises a showerhead comprising a plurality of apertures, wherein the showerhead comprises aluminum, and after exposing the showerhead to the process plasma the surface of the apertures comprises a thin film that comprises aluminum (Al) and nitrogen (N).

20. The method of claim 19, wherein the plurality of apertures comprise an inner channel, a sloped portion, and an outer channel, wherein the sloped portion fluidly connects the inner channel and the outer channel, and the residue is disposed on the sloped portion of at least one of the plurality of apertures.
